(19) United States
(12) Patent Application Publication
(10) Pub. No.: US 2014/0338734 A1
(43) Pub. Date: Nov. 20, 2014

(54) RESIN COMPOSITION, PRODUCTION METHOD THEREFOR, POLYETHYLENE TEREPHTHALATE FILM, AND BACK SHEET FOR SOLAR CELL MODULE

(71) Applicant: FUJIFILM Corporation, Tokyo (JP)

(72) Inventor: Makoto FUKUDA, Fujinomiya-shi (JP)

(73) Assignee: FUJIFILM Corporation, Tokyo (JP)

(21) Appl. No.: 14/449,269

(22) Filed: Aug. 1, 2014

Related U.S. Application Data
(63) Continuation of application No. PCT/JP2013/051700, filed on Jan. 28, 2013.

(30) Foreign Application Priority Data
Feb. 3, 2012 (JP) 2012-021865

(51) Int. Cl. C08G 73/16; H01L 31/048

(52) U.S. Cl. CPC C08G 73/16; H01L 31/0487
USPC 136/252; 525/437

(57) ABSTRACT

A resin composition comprising a polymer obtained by reacting polyethylene terephthalate with polycarbodiimide, wherein the decomposition rate of polycarbodiimide is from 1% to 40%, has a low decomposition rate of carbodiimide. The resin composition is capable of producing a film having excellent hydrolysis resistance.

### CROSS-REFERENCE TO RELATED APPLICATIONS

This application is a Continuation of PCT International Application No. PCT/JP2013/051700, filed Jan. 28, 2013, which claims priority under 35 U.S.C. Section 119(a) to Japanese Patent Application No. 2012-021865 filed on Feb. 3, 2012. Each of the above applications is hereby expressly incorporated by reference, in its entirety, into the present application.

### BACKGROUND OF THE INVENTION

1. Field of the Invention

The present invention relates to a resin composition, a production method therefore, a polyethylene terephthalate film and a back sheet for a solar cell module. More specifically, the present invention relates to a resin composition used as a master batch for improving the hydrolysis resistance of a PET film for a back sheet for a solar cell, a production method therefor, a polyethylene terephthalate film produced using the resin composition, and a back sheet for a solar cell module including the polyethylene terephthalate film.

2. Background Art

A solar cell module generally has a laminate structure in which a transparent filling material (which is hereinafter also referred to as a sealing material)/a photovoltaic cell/a sealing material/a back sheet (which is hereinafter also referred to as BS) are laminated in this order on a glass or front sheet on the light-receiving surface side to which sunlight is incident. Specifically, the photovoltaic cell is generally embedded with a resin (sealing material) such as EVA (an ethylene-vinyl acetate copolymer) and the like, and protective sheet for a solar cell is adhered thereto. Further, as this protective sheet for a solar cell, a polyester film, in particular, a polyethylene terephthalate (which is hereinafter also referred to as PET) film has been used.

However, the protective sheet for a solar cell, above all, a back sheet (BS) for a solar cell module, which becomes in particular an outermost layer, is considered to be under an environment exposed to weather outdoor for a long period of time, and therefore, excellent weather resistance is required.

Here, a polyester film such as PET and the like, which is also used as a back sheet for a solar cell module has excellent heat resistance, mechanical characteristics, chemical resistance, and the like, and therefore, is widely used industrially. However, it still needs to be improved from the viewpoint of hydrolysis resistance. Thus, as the technology for improving the hydrolysis resistance of a polyester film, for example, blending a polyester with an end capping agent such as polycarbodiimide and the like has been proposed (see, for example, Patent References 1 to 3 below).

In Reference Examples 3 and 4, and Example 1 of Patent Reference 1, an example in which master pellets of polycarbodiimide are produced by melt-kneading at 275° C. and a screw rotation of 200 rotations/min is described. In Examples 9 and 21 of Patent Reference 2, an example in which master pellets are produced by compounding polyethylene terephthalate with polycarbodiimide is described, but the details of the production condition is not described. In Examples of Patent Reference 3, an example in which master pellets of polycarbodiimide are produced using polybutylene terephthalate is described.

### CITATION LIST

### Patent References

Patent Reference 1: JP-A-2010-235824
Patent Reference 2: WO2010/110119
Patent Reference 3: JP-A-2002-194187

### SUMMARY OF INVENTION

As described above, there is a problem in that in a case where a polyester film is exposed to a wet heat atmosphere under an environment exposed to weather outdoor, embrittlement of the polyester film proceeds, and thus, the durability at break is lowered. The present inventors have made extensive studies thereon, and as a result, it could be seen that if a polyester film is under a high humidity and a high temperature, the moisture passes through the molecules of a non-crystalline portion having a low density of a polyester film and enters the inside to plasticize the non-crystalline portion and thus increase the mobility of the molecules. Further, the non-crystalline portion having an increase in the molecule mobility hydrolyzes the protons of a terminal carboxyl group of the polyester as a reaction catalyst. Thus, the polyester which is hydrolyzed and thus has a low molecular weight has a further increase in the molecule mobility, and thus, crystallization proceeds, which recurs that embrittlement of the film proceeds, thereby lowering the durability at break. Thus, it is one of important tasks to increase the hydrolysis resistance, in particular, as a polyester film used in a solar cell module.

However, a biaxially oriented polyester film produced using master pellets using the polycarbodiimide described in Patent References 1 to 3 as an end capping agent of a polyester does not still have a sufficient improvement in the hydrolysis resistance at present situation. In addition, these documents do not have a disclosure on a measure for further increasing the hydrolysis resistance.

The present invention has been made taking this situation into consideration, and it is a problem to be solved by the present invention to provide a resin composition having a low decomposition rate of carbodiimide, capable of producing a film having excellent hydrolysis resistance, and a production method therefor.

The present inventors have expected that a carboxylic acid and a polycarbodiimide, generated by the decomposition of a polyester, are reacted or a polycarbodiimide itself is decomposed with little moisture and heat, thereby producing isocyanate, which gives an adverse effect on hydrolysis resistance, and have thus investigated on stably kneading while inhibiting the decomposition of polyester and carbodiimide in production of master pellets of having a high end capping agent concentration. The present inventors have made extensive studies, and as a result, they have found that a resin composition having a low decomposition rate of carbodiimide capable of producing a film having excellent hydrolysis resistance can be produced, by selecting polyethylene terephthalate from polyesters and controlling a maximum temperature of a barrel and the number of screw rotation to specific ranges in the melt-kneading step in the production of master pellets can be obtained, thereby providing the present invention having the following configurations.

[1]A resin composition including a polymer obtained by reacting polyethylene terephthalate with polycarbodiimide, in which the decomposition rate of polycarbodiimide is from 1% to 40%.

[2] The resin composition as described in [1], the decomposition rate of polycarbodiimide is preferably from 1% to 30%.

[3]A method for producing a resin composition, including introducing a raw material composition containing polyethylene terephthalate and polycarbodiimide into a double-screw kneader having at least one barrel, a screw, and a vent, and melt-mixing the raw material composition in the double-screw kneader, in which the number of screw rotations of the double-screw kneader is controlled to from 80 rpm to 170 rpm, and the maximum temperature (Tmax) of the barrel of the double-screw kneader is controlled to satisfy the following formula (1):

Tm−5° C.≦Tmax≦Tm+15° C. Formula (1)

wherein Tm represents the melting point (unit: ° C.) of polyethylene terephthalate, and Tmax represents the maximum temperature (unit: ° C.) of the barrel.

[4] The method for producing a resin composition as described in [3], the number of screw rotations of the double-screw kneader is preferably controlled to from 80 rpm to 150 rpm.

[5] The method for producing a resin composition as described in [3] or [4], preferably, the double-screw kneader includes as the barrel a C1 barrel to which the raw material composition is introduced, and at least one other barrel arranged to be adjacent to the downstream of the C1 barrel, and the temperature of the C1 barrel is controlled to be lower than the melting point of polycarbodiimide by 10° C. or more.

[6] The method for producing a resin composition as described in any one of [3] to [5], preferably, the double-screw kneader includes as the barrel a C1 barrel to which the raw material composition is introduced, a C2 barrel arranged to be adjacent to the downstream of the C1 barrel, and C3 barrel arranged to be adjacent to the downstream of the C2 barrel, and the minimum temperature (Tmin) of the barrel after the C3 barrel satisfies the following formula (2):

Tm−15° C.≧Tmin≧Tm−65° C. Formula (2)

wherein Tm represents the melting point (unit: ° C.) of polyethylene terephthalate, and Tmin represents the minimum temperature (unit: ° C.) of the barrel.

[7] The method for producing a resin composition as described in any one of [3] to [6], the water content of the polyethylene terephthalate at a time of introduction into the double-screw kneader is preferably 150 ppm or less.

[8] The method for producing a resin composition as described in any one of [3] to [7], the temperature of the polyethylene terephthalate at a time of introduction into the double-screw kneader is preferably 160° C. or lower.

[9] The method for producing a resin composition as described in any one of [3] to [8], the double-screw kneader preferably has two or more vents.

[10] A resin composition produced by the method for producing a resin composition as described in any one of [3] to [9].

[11] A polyethylene terephthalate film fabricated by the addition of the resin composition as described in any one of [1], [2], and [10].

[12] A back sheet for a solar cell module, including the polyethylene terephthalate film as described in [11].

According to the present invention, a resin composition having a low decomposition rate of carbodiimide, which is capable of producing a film having excellent hydrolysis resistance, can be provided.

### BRIEF DESCRIPTION OF DRAWINGS

FIG. 1 is a schematic view showing one example of the cross-section of the double-screw kneader which can be used in the present invention.

### DESCRIPTION OF EMBODIMENTS

Hereinafter, the resin composition, the production method therefor, the polyethylene terephthalate film, and the back sheet for a solar cell module of the present invention will be described in detail.

The description of the constitutive elements as described below is based on typical embodiments of the present invention, but the present invention should not be limited thereto. Further, the numerical range expressed by the wording “(a lower limit) to (an upper limit)” means a range that falls between the former number indicating the lower limit of the range and the latter number indicating the upper limit thereof.

[Resin Composition]

The resin composition of the present invention includes a polymer obtained by reacting polyethylene terephthalate with polycarbodiimide, in which the decomposition rate of polycarbodiimide is from 1% to 40%.

If the resin composition of the present invention is used, the polyethylene terephthalate film of the present invention as described later, which has excellent hydrolysis resistance, can be produced by the configuration above. Specifically, if an oligomer-based end capping agent such as polycarbodiimide is blended with polyethylene terephthalate, it is often reacted with a terminal group of the polyethylene terephthalate to form a polymer, and can reduce acid values (which may be hereinafter abbreviated as “AV” in some cases) derived from the number of the initial terminal COOH groups of polyethylene terephthalate. Such a polyethylene terephthalate film is less likely to be hydrolyzed due to a reduced number of terminal COOH groups involved in hydrolysis.

The resin composition of the present invention preferably includes the polycarbodiimide, in addition to the polymer. The resin composition of the present invention may further include isocyanate. Further, isocyanate is preferably derived from the polycarbodiimide, and it does not need to be positively added intentionally.

Furthermore, the resin compositions of the present invention are not formed of a polymer obtained by the reaction of the polyethylene terephthalate with polycarbodiimide, and may further include the polyethylene terephthalate.

Further, within a range not interfering with the effects of the present invention, various additives, for example, a compatibilizer, a plasticizer, a weathering agent, an antioxidant, a thermal stabilizer, a lubricant, an antistatic agent, a brightener, a colorant, a conductive agent, an ultraviolet absorber, a flame retardant, a flame retardant auxiliary agent, a pigment, a dye, or the like may be added to the resin composition of the present invention.

(Polymer)

The polymer obtained by the reaction of polyethylene terephthalate with polycarbodiimide, which is included in the resin composition of the present invention, will be described.

Polyethylene Terephthalate

The polyethylene terephthalate has a —COO— bond or a —OCO— bond in the middle of the polymer. Further, the terminal group of the polyethylene terephthalate is a linear saturated polyester synthesized from an aromatic dibasic acid or an derivative for forming an ester thereof, a diol or an derivative for forming an ester thereof as an OH group, a COOH group, or a protected group thereof (an OR^{X} group, a COOR^{X} group (R^{X} is any substituent such as an alkyl group and the like). As the polyethylene terephthalate, for example, those described in JP-A-2010-235824 can be appropriately used.

The polyethylene terephthalate (PET) is particularly preferred from the viewpoint of the balance between the mechanical properties and the cost.

The polyethylene terephthalate may be a homopolymer or a copolymer. Further, it may be a blend of the polyethylene terephthalate with a small amount of any other type of resin, for example, polyimide, or the like. It is also possible to use a crystalline polyester which can form anisotropy during the melting as the polyethylene terephthalate.

The terminal carboxyl group content in the polyethylene terephthalate (the carboxylic acid value of the resin) is preferably 20 eq/ton or less, and more preferably 15 eq/ton or less, with respect to the polyester. If the carboxyl group content is 20 eq/ton or less, the hydrolysis resistance is maintained, and thus, reduction of strength at a time of wet heat aging can be inhibited low. The lower limit of the terminal carboxyl group content is desirably 5 eq/ton or more from the viewpoint of keeping the adhesiveness among various functional layers (for example, a white layer) of the back sheet for a solar cell module, which are formed with the polyethylene terephthalate film of the present invention as described later. The terminal carboxyl group content in the polyethylene terephthalate can be adjusted by the kind of a polymerization catalyst, the polymerization time, or the film formation conditions (the film formation temperature and time). The carboxyl group content can be measured by a titration method according to the method described in H. A. Pohl, Anal. Chem. 26 (1954) 2145. Specifically, a polyester is dissolved in benzyl alcohol at 205° C. and a phenol red indicator is added. Then, titration is performed with a water/methanol/benzyl alcohol solution of sodium hydroxide, and from the titration amount, the carboxylic acid value (eq/ton) can be calculated.

The terminal hydroxyl group content in the polyethylene terephthalate is preferably 120 eq/ton or less, and more preferably 90 eq/ton or less, with respect to the polyethylene terephthalate. If the hydroxyl group content is 120 eq/ton or less, the reaction between polycarbodiimide and the hydroxyl group is inhibited, and thus, the reaction with a carboxyl group is preferentially undergone, which can further reduce the carboxylic acid value. The lower limit of the hydroxyl group content is preferably 20 eq/ton from the viewpoint of adhesion with an upper layer. The hydroxyl group content in the polyethylene terephthalate can be adjusted by the kind of a polymerization catalyst, the polymerization time, or the film formation conditions (the film formation temperature and time). For the terminal hydroxyl group content, a value measured by ¹H-NMR, using a deuterated hexafluoroisopropanol solvent, can be used.

The intrinsic viscosity (IV) of the polyethylene terephthalate is preferably from 0.5 dl/g to 0.9 dl/g, more preferably from 0.55 dl/g to 0.85 dl/g, and particularly preferably from 0.6 dl/g to 0.85 dl/g, from the viewpoints of setting the intrinsic viscosity after film formation in the preferred range as described later and stirring properties during the synthesis with polycarbodiimide as described later.

For the molecular weight of the polyethylene terephthalate, the weight average molecular weight (Mw) is preferably from 5000 to 30000, more preferably from 8000 to 26000, and particularly preferably from 12000 to 24000, from the viewpoints of heat resistance and viscosity. As the weight average molecular weight of the polyethylene terephthalate, a value in terms of polymethyl methacrylate (PMMA), measured by gel permeation chromatography (GPC) using hexafluoroisopropanol as a solvent, can be used.

The polyethylene terephthalate can be synthesized according to a known method. For example, polyethylene terephthalate can be synthesized according to a known polycondensation method, a ring-opening polymerization method, or the like, which can be applied to any one of the reactions by transesterification reaction and direct polymerization.

The polyethylene terephthalate used in the present invention is a polymer or copolymer, obtained by the condensation reaction of an aromatic dibasic acid or an derivative for forming an ester thereof with a diol or an derivative for forming an ester thereof as a main components, and can be produced by subjecting an aromatic dibasic acid or an derivative for forming an ester thereof, and a diol or an derivative for forming an ester thereof to esterification reaction or transesterification reaction, and then to polycondensation reaction. Further, by selecting the raw material or the reaction condition, the carboxylic acid value or the intrinsic viscosity of the polyethylene terephthalate can be controlled. Further, in order to perform the esterification or transesterification reaction and the polycondensation reaction effectively, it is preferable to add a polymerization catalyst during these reactions.

As a polymerization catalyst in the polymerization of the polyethylene terephthalate, an Sb-based, Ge-based, or Ti-based compound is preferably used from the viewpoint of inhibiting the carboxyl group content to a predetermined range or less. Among these, a Ti-based compound is particularly preferred. In the case of using a Ti-based compound, in a preferred embodiment, the Ti-based compound is used as the catalyst in the range of the amount of 1 ppm to 30 ppm, and more preferably from 3 ppm to 15 ppm to perform polymerization. If the proportion of the Ti-based compound is within the range, it is possible to adjust the terminal carboxyl groups to fall within the range as described below, and it is also possible to keep the hydrolysis resistance of the polymer substrate low.

In the synthesis of the polyethylene terephthalate using a Ti-based compound, for example, the methods described in JP-B-8-301198, Japanese Patents 2543624, 3335683, 3717380, 3897756, 3962226, 3979866, 3996871, 4000867, 4053837, 4127119, 4134710, 4159154, 4269704, 4313538, or the like may be applied.

Preferably, the polyethylene terephthalate is one subjected to solid-phase polymerization after polymerization. This can result in the preferred carboxyl group content. The solid-phase polymerization may be in a continuous method (where the resin is filled in a tower, gradually circulated therein with heating for a predetermined period of time, and then discharged) or in a batch method (where the resin is put into a container and heated therein for a predetermined period of time). Specifically, the methods described in Japanese Patents 2621563, 3121876, 3136774, 3603585, 3616522, 3617340, 3680523, 3717392, 4167159, or the like may be applied to the solid-phase polymerization.

The temperature of the solid-phase polymerization is preferably from 170° C. to 240° C., more preferably from 180° C. to 230° C., and even more preferably from 190° C. to 220° C. The time of the solid-phase polymerization is preferably from 5 hours to 100 hours, more preferably from 10 hours to 75 hours, and even more preferably from 15 hours to 50 hours. The solid-phase polymerization is preferably carried out in vacuum or in a nitrogen atmosphere.

The resin composition of the present invention includes the polyethylene terephthalate in the amount of preferably 70% by mass to 95% by mass, more preferably 75% by mass to 95% by mass, and particularly preferably 80% by mass to 95% by mass, with respect to the total resin composition, in addition to the polymer obtained by the reaction of the polyethylene terephthalate with polycarbodiimide.

Polycarbodiimide

The polycarbodiimide is a compound having a structure (a carbodiimido group) represented by (—N═C═N—), and can be produced, for example, by heating an organic isocyanate, in the presence of an appropriate catalyst, to perform a decarboxylation reaction. A polycarbodiimide having a number average molecular weight of 18000 or more is preferably used. As the number average molecular weight of polycarbodiimide, a number average molecular weight in terms of polystyrene standards may be used, which is obtained by dissolving polycarbodiimide powder in a single solvent or a mixed solvent of two or more kinds selected from chloroform, tetrahydrofuran (THF), N-methyl-2-pyrrolidone (NMP), and hexafluoroisopropanol (HFIP), and measuring the curve of a molecular weight distribution curve using GPC.

If the number average molecular weight of the polycarbodiimide is less than 18000, the volatility is increased, and as a result, the degree of reduction of the reaction rate coefficient becomes low. Further, the upper limit of the polycarbodiimide is not particularly limited as long as it does not affect the effect of the present invention adversely, but from the viewpoint of the mobility of a polymer chain, the upper limit is preferably 30000 or less. The number average molecular weight of the polycarbodiimide is preferably from 18000 to 30000, and more preferably from 18000 to 28000, from the viewpoints of volatility and the mobility of a polymer chain.

The polycarbodiimide can be selected from compounds obtained by polymerizing aliphatic diisocyanate, alicyclic diisocyanate, aromatic diisocyanate, or a mixture thereof. Specific examples of the polycarbodiimide include polycarbodiimides such as poly(1,6-hexamethylenecarbodiimide), poly(4,4′-methylene-biscyclohexylcarbodiimide), poly(1,3-cyclohexylenecarbodiimide), poly(1,4-cyclohexylenecarbodiimide), poly(4,4′-dicyclohexylmethanecarbodiimide), poly(4,4′-diphenylmethanecarbodiimide), poly(3,3′-dimethyl-4,4′-diphenylmethanecarbodiimide), poly(naphthylenecarbodiimide), poly(p-phenylenecarbodiimide), poly(m-phenylenecarbodiimide), poly(tolylcarbodiimide), poly(diisopropylcarbodiimide), poly(methyldiisopropylphenylenecarbodiimide), poly(1,3,5-triisopropylbenzene)polycarbodiimide, poly(1,3,5-triisopropylbenzene and 1,5-diisopropylbenzene)polycarbodiimide, poly(triethylphenylenecarbodiimide), poly(triisopropylphenylenecarbodiimide), and the like; etc. Further, as a commercially available product, “STABAXOL” (manufactured by Rhein Chemie Japan Ltd.), or the like can be used. Specifically, examples of the polycarbodiimide include STABAXOL P (molecular weight of 3000 to 4000, manufactured by Rhein Chemie Japan Ltd.) and LA-1 (molecular weight of about 2000, manufactured by Nisshinbo Chemical Inc.). Examples of the polycarbodiimide further include STABAXOL P400 (molecular weight of about 20000, manufactured by Rhein Chemie Japan Ltd.) and STABILIZER 9000 (molecular weight of about 20000, manufactured by Rhein Chemie Japan, Ltd.). Among these, preferred is the polycarbodiimide having a large weight average molecular weight such as STABAXOL P400, STABILIZER 9000, or the like.

Above all, the polycarbodiimide is preferably a compound obtained by polymerizing aromatic diisocyanate, and is preferably a polycarbodiimide having a unit structure represented by the following formula (1).

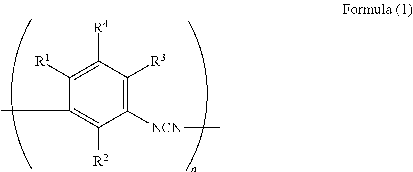

R¹, R², R³, R⁴ each independently represent an alkyl group having 1 to 7 carbon atoms or a hydrogen atom. n represents the number of recurring units.

As the polycarbodiimide which is obtained by the polymerization of aromatic diisocyanate and has a unit structure represented by the formula (1), poly(1,3,5-triisopropylphenylene-2,4-carbodiimide), poly(1,5-diisopropylphenylene-2,4-carbodiimide), and any copolymer thereof can be appropriately used.

The melting point of the polycarbodiimide is preferably from 50° C. to 200° C., more preferably from 100° C. to 180° C., and particularly preferably from 155° C. to 160° C.

The polycarbodiimide can be synthesized by heating diisocyanate (for example, 2,4,6-triisopropylphenyl-1,3-dicyanate) and phospholene oxide (for example, 3-methyl-1-phenyl-2-phospholene oxide). The number average molecular weight of polycarbodiimide can be controlled by selecting the addition amount of the respective materials or the reaction time.

The resin composition of the present invention includes the polycarbodiimide in the amount of preferably 0.1% by mass to 30% by mass, more preferably 1% by mass to 25% by mass, and particularly preferably 1% by mass to 20% by mass, with respect to the total resin composition, in addition to the polymer obtained by the reaction of the polyethylene terephthalate with polycarbodiimide.

Structure of Polymer

The structure of a polymer obtained by the reaction of polyethylene terephthalate with polycarbodiimide will be described.

By blending the polyester with carbodiimide to perform a reaction, a polymer containing a site at which at least one selected from the polycarboimides is bonded to a terminal of the polyester is synthesized.

The resin composition of the present invention includes the polymer obtained by the reaction of the polyethylene terephthalate with polycarbodiimide in the amount of preferably 5% by mass to 30% by mass, more preferably 5% by mass to 25% by mass, and particularly preferably 5% by mass to 20% by mass, with respect to the total resin composition.

As described above, examples of the terminal group of the polyethylene terephthalate include an OH group, a COOH group, or a protected group thereof (an OR^{X} group and a COOR^{X} group).

For example, in the case where a polycarbodiimide is bonded to a COOH (COOR^{X}) terminal group of polyethylene terephthalate, it is considered that a reaction represented by the following scheme occurs.

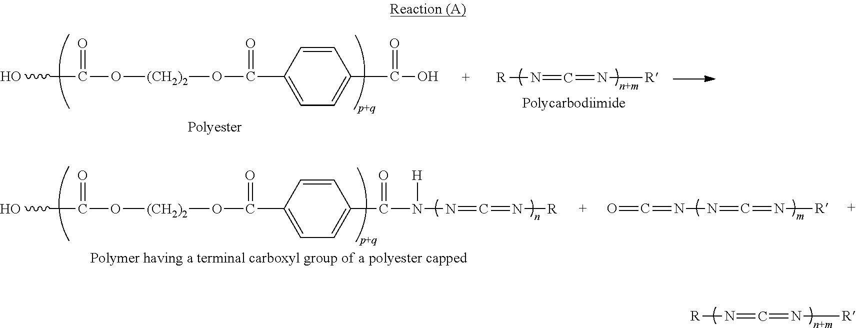

Isocyanate produced by decomposition Residual polycarbodiimide

In addition, there are cases where the terminal group of polyethylene terephthalate is bonded to a moiety other than a terminal of the polycarbodiimide. For example, it is a preferred case where a polycarbodiimide is bonded to the COOH (COOR^{X}) terminal group of polyethylene terephthalate.

Here, even when the polymer in a certain structure is formed, in order to increase the hydrolysis resistance of polyethylene terephthalate, it is preferable that polyethylene terephthalate cap many carboxyl terminals. Accordingly, it is preferable to introduce excessive polycarbodiimide, with respective to the number of molecules of the terminal carboxylic acid of polyethylene terephthalate.

However, if the hydrolysis proceeds before capping the terminal of the raw material polyethylene terephthalate, carbodiimide is significantly decomposed. Specifically, if the raw material polyethylene terephthalate is hydrolyzed according to the following reaction (B), polyethylene terephthalate having a small molecular weight is generated, whereby the amount of carboxyl groups per ton of polyethylene terephthalate is significantly increased. Accordingly, the equivalents of the terminal group of polyethylene terephthalate supplied to the reaction (A) are increased, and thus, the amount of polycarbodiimide required for end capping is also increased. Further, the amount of polycarbodiimide consumed is increased, whereby the amount of isocyanate produced is also increased.

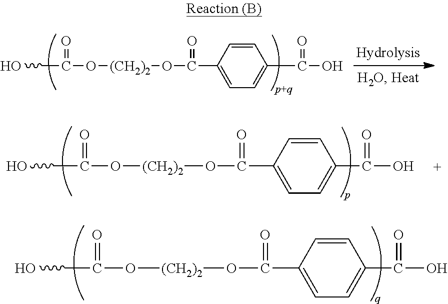

Furthermore, although not shown in the reaction scheme, the polycarbodiimide introduced in a large amount for a secondary reaction remains as the unreacted polycarbodiimide, and further, it may be reacted with moisture, polyethylene terephthalate, or free acids, thus to be decomposed into isocyanates in some cases.

For these factors, a resin composition having a high decomposition rate of polycarbodiimide is configured to have insufficient end capping of the polyethylene terephthalate, and if the resin composition having insufficient end capping is used to form a polyethylene terephthalate film, there occurs a problem in hydrolysis resistance.

Incidentally, if a resin composition including a large amount of isocyanate is used as a master pellet, generation of contaminations in a process in the formation of a polyethylene terephthalate film, deterioration of a surface shape of a polyethylene terephthalate film obtained by burst-out, or a problem in adhesion among the layers in use for a polymer sheet for a solar cell module may occur.

Further, the produced isocyanate having a molecular weight large to a certain degree is reacted with moisture, polyethylene terephthalate, or free acids, thus to be decomposed into isocyanates in some cases, and therefore a lower molecular weight isocyanate is easily volatilized.

(Characteristics of Resin Composition)

As such, the resin composition of the present invention has a decomposition rate of polycarbodiimide of from 1% to 40%. Since the resin composition of the present invention has a low decomposition rate of polycarbodiimide, the end capping of polyethylene terephthalate is sufficient. As a result, if the resin composition of the present invention is used as a master pellet, a polyethylene terephthalate film having good hydrolysis resistance can be obtained.

In addition, since the resin composition of the present invention has a low decomposition rate of polycarbodiimide, the amount of isocyanate contained is small. As a result, if the resin composition of the present invention is used as a master pellet, the contamination in the process due to volatilization of an isocyanate gas is decreased in the formation of a polyethylene terephthalate film having good hydrolysis resistance, and due to reduced burst-out to the film surface by thickening or generation of a gel, the surface shape of the obtained polyethylene terephthalate film becomes better. Further, if this polyethylene terephthalate film of the present invention is used for polymer sheet for a solar cell module, a problem in adhesion among the layers is reduced, and thus, particularly, adhesion among the layers after wet heat aging can be greatly improved.

The decomposition rate of polycarbodiimide in the resin composition of the present invention is preferably from 1% to 30%, and more preferably from 1 to 20%.

A method for calculating the decomposition rate of polycarbodiimide in the resin composition of the present invention is not particularly limited, but in the present invention, a sample obtained by mixing powder formed by pulverizing polyethylene terephthalate with powder of polycarbodiimide at an any ratio is subjected to infrared spectrometry and a calibration curve of the amount of polycarbodiimide in polyethylene terephthalate at a peak intensity of 2140 cm⁻¹ and 2960 cm⁻¹ is produced. A sample obtained by pulverizing the resin composition of the present invention (master pellet) is subjected to infrared spectrometry, and based on the calibration curve, the amount of polycarbodiimide in polyethylene terephthalate is calculated and the decomposition with respect to the amount of the polycarbodiimide used is calculated.

The resin composition of the present invention may be introduced to a double-screw kneading extruder so as to be provided as it is for melt-formation of a polyester film, or may be prepared to be a master pellet (which may also be referred to as a master batch in some cases) including polycarbodiimide at a high concentration, diluted with a polyester resin, and introduced to a double-screw kneading extruder. Above all, the resin composition of the present invention may be appropriately used as a master pellet including polycarbodiimide at a high concentration.

Further, the master pellet is a pellet in which additives (end capping agents) are dispersed at a high concentration (finally 3- to 100-fold concentration of the final concentration in the film after the film formation), and when being extruded, the pellet is used after being diluted to a pellet without addition of an end capping agent. Thus, as compared with a direct addition method, contamination of a supply port (hopper) in the extruder with an end capping agent, or generation of loss due to part number conversion, or the like hardly occurs, and accordingly, the productivity of a polyester resin composition in which the end capping agent and the like are dispersed, or a molded product thereof (for example, a film) is increased.

The resin composition of the present invention is produced by the production method for the resin composition of the present invention as described below. Hereinafter, the production method for the resin composition of the present invention will be described.

[Production Method for Resin Composition]

The production method for the resin composition of the present invention includes introducing a raw material composition containing polyethylene terephthalate and polycarbodiimide into a double-screw kneader having at least one barrel, a screw, and a vent; and melt-mixing the raw material composition in the double-screw kneader, in which the number of screw rotations of the double-screw kneader is controlled to from 80 rpm to 170 rpm, and the maximum temperature (Tmax) of the barrel of the double-screw kneader is controlled to satisfy the following formula (1).

Tm−5° C.≦Tmax≦Tm+15° C. Formula (1)

In the formula (1), Tm represents the melting point (unit: ° C.) of polyethylene terephthalate, and Tmax represents the maximum temperature (unit: ° C.) of the barrel.

In the melt-mixing step, mixing is carried out using a double-screw extruder.

In the production method for the resin composition of the present invention, by controlling the maximum temperature of the barrel to an upper limit or less, the decomposition of the polyester can be inhibited. Therefore, the equivalents of the polyester provided to a reaction with polycarbodiimide can be reduced, and thus, the amount of isocyanate produced by the end capping can be reduced. As a result, the resin composition of the present invention having a low decomposition rate of polycarbodiimide can be produced.

By controlling maximum temperature of the barrel to a lower limit value or more, the melt viscosity is not too much increased and the unmelted portion is reduced, thereby improving the production stability of the resin composition of the present invention.

It is more preferable that the maximum temperature (Tmax) of the barrel of the double-screw kneader be controlled to satisfy the following formula (1′) from the viewpoint of reducing the decomposition rate of carbodiimide.

Tm−5° C.≦Tmax≦Tm+10° C. Formula (1′)

In the formula (1′), Tm represents the melting point (unit: ° C.) of polyethylene terephthalate, and Tmax represents the maximum temperature (unit: ° C.) of the barrel.

Moreover, by controlling the number of screw rotations to an upper limit or less, the decomposition of the polyester can be inhibited, and thus, the amount of isocyanate produced by the end capping can be reduced. As a result, the resin composition of the present invention having a low decomposition rate of polycarbodiimide can be produced. On the other hand, by controlling the number of screw rotations to a lower limit value or more, the decomposition rate of polycarbodiimide can be reduced to be low.

In the production method for the resin composition of the present invention, it is preferable that the number of screw rotations of the double-screw kneader be controlled to from 80 rpm to 150 rpm from the viewpoint of further reducing the decomposition rate of carbodiimide.

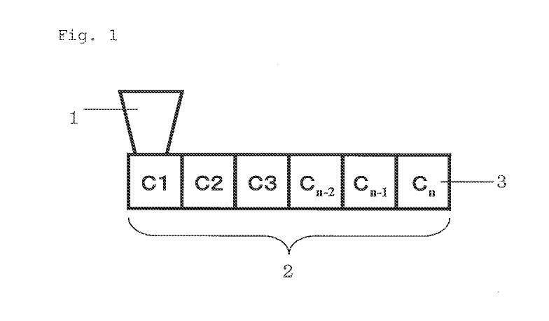

The configuration of the double-screw extruder used in production method for the resin composition of the present invention is shown in FIG. 1. In FIG. 1, a raw material composition is added from a hopper 1. The raw material composition added is discharged through a discharge port from the downstream-most barrel 3 via a plurality of barrels 2.

In the production method for the resin composition of the present invention, a vent type double-screw kneader is used, from the viewpoint of inhibition of the hydrolysis of the polyester and the polycarbodiimide.

In the present invention, it is preferable that the double-screw kneader have two or more vents. If the number of vents is 2 or more, the decomposition of the polyester can be inhibited, whereby the reaction rate of the polycarbodiimide can be reduced, and further the hydrolysis of the polycarbodiimide itself can be reduced, whereby the amount of the isocyanate gas can be reduced. The number of vents is more preferably 2. Further, the position of the vent in the double-screw kneader is not particularly limited. In the case of arranging a barrel having a kneading, the barrel is preferably provided in a barrel in the downstream of the barrel having a kneading. Further, the double-screw kneader preferably has a screw configuration such as a kneading segment, a kneading rotor, or the like as the kneading portion.

The ratio (L/D) of the length (L) of the screw to the diameter (D) of the screw in the double-screw kneader is not particularly limited, but from the viewpoint of dispersibility of the end capping agent, the ratio is preferably from 20 to 80, more preferably from 25 to 70, even more preferably from 30 to 65, and particularly preferably from 30 to 60.

The rotation directions of the respective screws may be either the same directions or the different directions.

(Introduction of Raw Materials)

In the production method for the resin composition of the present invention, the water content of the polyethylene terephthalate at a time of introduction into the double-screw kneader is preferably 150 ppm or less.

If the water content of the polyethylene terephthalate at a time of introduction into the double-screw kneader is 150 ppm or less, the decomposition of polyethylene terephthalate and polycarbodiimide can be inhibited. Therefore, the amount of isocyanate gas produced can also be inhibited. The water content of the polyethylene terephthalate at a time of introduction into the double-screw kneader is more preferably 120 ppm or less.

On the other hand, when the water content of the polyethylene terephthalate at a time of introduction into the double-screw kneader is high to a certain degree, it is possible to inhibit the polycarbodiimide from being melted at the base of the hopper to fuse the polyethylene terephthalate, thereby improving the production stability. The water content of the polyethylene terephthalate at a time of introduction into the double-screw kneader is preferably 80 ppm or more.

In the production method for the resin composition of the present invention, the temperature of the polyethylene terephthalate at a time of introduction into the double-screw kneader is preferably 165° C. or lower, from the viewpoint that the water content of the polyethylene terephthalate at a time of introduction into the double-screw kneader can be reduced, and the temperature is more preferably 160° C. or lower.

The temperature of the polyethylene terephthalate at a time of introduction into the double-screw kneader is preferably 60° C. or higher, and more preferably 80° C. or higher.

In a method for supplying raw materials to the double-screw kneader, from the viewpoint of the operability and the dispersibility of the end capping agent, a method in which the respective raw materials are individually and directly supplied, or a method in which all the raw materials are mixed in advance and then supplied at once is preferred. In addition, the supply of the raw materials is preferably carried out using a weight feeder, from the viewpoint of extrusion stability.

In the case of producing the resin composition of the present invention as a master pellet, the initial introduction amount of polycarbodiimide is preferably from 1% by mass to 30% by mass, more preferably from 1% by mass to 25% by mass, and particularly preferably from 5% by mass to 20% by mass, with respect to the total resin composition.

(Melt-Mixing)

In the production method for the resin composition of the present invention, preferably, the double-screw kneader includes a C1 barrel to which the raw material composition is introduced and at least one other barrel arranged to be adjacent to the downstream of the C1 barrel as the barrel, and the temperature of the C1 barrel is controlled to be lower than the melting point of polycarbodiimide by 10° C. or more.

When the temperature of the C1 barrel is lower than the melting point of the polycarbodiimide by 10° C. or more, the water content of the raw material composition can be reduced, and thus, it is possible to inhibit the polycarbodiimide from being melted at the base of the hopper to fuse the PET, thereby improving the production stability. The temperature of the C1 barrel is lower than the melting point of the polycarbodiimide by preferably 20° C. or more and more preferably 30° C. or more.

Preferably, the double-screw kneader used in the present invention includes a C1 barrel to which the raw material composition is introduced, and a C2 barrel arranged to be adjacent to the downstream of the C1 barrel as the barrel.

The temperature of the C2 barrel is preferably from the temperature of the C1 barrel or higher, and is preferably from the temperature of the third barrel as described below or lower.

Furthermore, the double-screw kneader more preferably includes a C3 barrel arranged to be adjacent to the downstream of the C2 barrel.

The number of the barrels included in the double-screw kneader is particularly preferably from 4 to 10, and more particularly preferably from 6 to 8.

In the production method for the resin composition of the present invention, preferably, the double-screw kneader includes a C1 barrel to which the raw material composition is introduced, a C2 barrel arranged to be adjacent to the downstream of the C1 barrel, and at least C3 barrel arranged to be adjacent to the downstream of the C2 barrel as the barrel, and the minimum temperature (Tmin) of the barrel after the C3 barrel satisfies the following formula (2).

Tm−15° C.≧Tmin≧Tm−65° C. Formula (2)

In the formula (2), Tm represents the melting point (unit: ° C.) of polyethylene terephthalate, and Tmin represents the minimum temperature (unit: ° C.) of the barrel.

The minimum temperature (Tmin) of the barrel after the C3 barrel is preferably Tm−65° C. or higher from the viewpoint of stably producing a master pellet. On the other hand, the minimum temperature (Tmin) of the barrel after the C3 barrel is preferably Tm−15° C. or lower from the viewpoint that the decomposition rate of polyethylene terephthalate can be reduced, and thus, the decomposition rate of polycarbodiimide can be inhibited.

The minimum temperature (Tmin) of the barrel after the C3 barrel more preferably satisfies the following formula (2′) from the viewpoint that the surface shape of the polyethylene terephthalate film is improved.

Tm−15° C.≧Tmin≧Tm−55° C. Formula (2′)

In the formula (2′), Tm represents the melting point (unit: ° C.) of polyethylene terephthalate, and Tmin represents the minimum temperature (unit: ° C.) of the barrel.

The maximum temperature of the barrel after the C3 barrel is preferably in the range of the above-described formula (1), and more preferably the range of the formula (1′).

In the present invention, from the viewpoint of obtaining a resin composition having a stable good hue, it is preferable to introduced an inert gas such as nitrogen and the like, or melt-knead under a reduced pressure condition.

The resin composition thus melt-kneaded is then discharged from the double-screw kneader by any method, and thus, the resin composition of the present invention can be obtained.

It is preferable that the resin composition of the present invention be molded to a pellet shape from the viewpoint of the handability in the production of the polyethylene terephthalate film as described below. A method for molding to a pellet shape is not particularly limited, but the resin composition is preferably, for example, extruded to a strand shape from the double-screw kneader, cooled with water, and cut into a pellet.

A desired molded article can be obtained by grounding or pulverizing the resin composition of the present invention into a pellet or powder, diluting and blending the pellet or powder with a polyester resin or the like, and introducing it into a molding device in which another mold in a desired shape is arranged. For example, the resin composition is preferably molded into a polyethylene terephthalate film.

[Polyethylene Terephthalate Film]

The polyethylene terephthalate film of the present invention may be fabricated by the addition of the resin composition of the present invention.

<Configuration of Polyethylene Terephthalate Film>

The polyethylene terephthalate film of the present invention preferably contains the polymer having the above-described structure.

The thickness of the polyethylene terephthalate film of the present invention varies according to the uses, but in the case where the polyethylene terephthalate film is used as a member of a back sheet for a solar cell module, the thickness is preferably from 25 μm to 300 μm, and more preferably from 120 μm to 300 μm. When the thickness is 25 μm or more, a sufficient dynamic strength is obtained, whereas a thickness set to be 300 μm or less is advantageous in terms of cost.

The polyethylene terephthalate film of the present invention is preferably stretched, and more preferably biaxially stretched. The degree of MD orientation and the degree of TD orientation of the polyethylene terephthalate film of the present invention are each preferably 0.14 or more, more preferably 0.155 more, and particularly preferably 0.16 or more. If each degree of orientation is 0.14 or more, the restriction of the non-crystalline chain is improved (the mobility is lowered), and the wet heat resistance is improved. The degree of MD orientation and the degree of TD orientation can be calculated from the degree of MD orientation: Δn(x-z), TD; Δn(y-z), by measuring the refractive indices in the x, y, and z directions of the biaxially oriented film at an atmosphere at 25° C., using an Abbe refractometer, a monochromatic light sodium D-line as the light source, and methylene iodine as a mount solution.

Furthermore, the intrinsic viscosity (IV) of the polyethylene terephthalate film of the present invention is preferably from 0.55 dl/g to 0.9 dl/g, more preferably from 0.6 dl/g to 0.85 dl/g, and particularly preferably from 0.62 dl/g to 0.82 dl/g, from the viewpoints of setting the intrinsic viscosity after film formation to the preferred range as described later, and stirring properties during the synthesis with polycarbodiimide.

<Production Method for Polyethylene Terephthalate Film>

(Film Forming Step)

In the film forming step, the polyethylene terephthalate and the polymer (melt) included in the resin composition of the present invention is passed through a gear pump or a filter, then extruded from a cooling roll through a die, and cooled and solidified, whereby a (unstretched) film can be formed. In this regard, the extruded melt can be adhered to the cooling roll using an electrostatic application method. At this time, the surface temperature of the cooling roll can be usually set to 10° C. to 40° C.

(Stretching Step)

The (unstretched) film formed by the film forming step can be realized by carrying out a stretching treatment in the stretching step. In the stretching step, a cooling-solidified (unstretched) film is preferably stretched in one or two directions, and more preferably stretched in two directions. The stretching in two directions (biaxial stretching) is preferably stretching in the length direction (MD: Machine Direction) (which is hereinafter also referred to as “longitudinal stretching”) and in the width direction (TD: Transverse Direction) (which may be hereinafter also referred to as a “transverse stretching”. The longitudinal stretching and the transverse stretching can be carried out once, respectively, or may be carried out in plural times, and the longitudinal stretching and the transverse stretching may be carried out at the same time.

The stretching treatment is carried out, preferably at the glass temperature (Tg)° C. of the film to (Tg+60)° C., and more preferably Tg+3° C. to Tg+40° C., and more preferably at Tg+5° C. to Tg+30° C.

The preferred stretching ratio is from 280% to 500%, more preferably from 300% to 480%, and even more preferably from 320% to 460% in at least one direction. In the case of biaxial stretching, the stretching may be carried out equivalently in the longitudinal and the transverse directions, but it is more preferable that the stretching ratio in one direction is larger than that in the other direction, thereby carrying out inequivalent stretching. Any one of the longitudinal direction (MD) and the transverse direction (TD) may be larger than the other. The stretching ratio as mentioned herein is determined using the following formula.

Stretching ratio(%)=100×{(Length after stretching)−(Length before stretching)}/(Length before stretching)

The biaxial stretching treatment is a stretching, for example, at the glass transition temperature (Tg₁)° C. of a film to (Tg₁+60)° C. in the length direction once or two or more times, in which the total ratio is 3- to 6-times and the ratio in the width ration at (Tg₁)° C. to (Tg+60)° C. is 3- to 5-times.

The biaxial stretching treatment can be carried out by stretching in the length direction, using two or more nip rolls that have a higher peripheral speed at an outlet (longitudinal stretching), and can also carried out by gripping both ends of the film with chucks and extending them in the perpendicular direction (the direction perpendicular to the length direction) (transverse stretching).

In the stretching step, before the stretching treatment or after the stretching treatment, and preferably after stretching treatment, the film can be subjected to a heat treatment. By carrying out the heat treatment, fine crystals can be produced, thereby improving the dynamic characteristics or durability. The film can also be subjected to a heat treatment at about 180° C. to 210° C. (more preferably at 185° C. to 210° C.) for 1 second to 60 seconds (more preferably for 2 seconds to 30 seconds).

In the stretching step, the thermal relaxation treatment can be carried out after the heat treatment. The thermal relaxation treatment is a treatment for shrinking the film by applying heat to the film for stress relaxation. The thermal relaxation treatment is preferably carried out in both directions of the MD direction and the TD direction of the film. For the conditions in the thermal relaxation treatment, the treatment is preferably carried out at a temperature lower than the heat treatment temperature, and more preferably at 130° C. to 205° C. Further, for the thermal relaxation treatment, the thermal shrinkage (150° C.) of the film in both of the MD and the TD is preferably from 1% to 12%, and more preferably from 1% to 10%. However, the thermal shrinkage (150° C.) is determined as follows. The thermal shrinkage can be determined from the following formula, by cutting out a sample having a width of 50 mm at 350 mm in the measurement direction, attaching a target point at an interval of 300 mm near the both ends in the length direction of the sample, fixing one end in an oven adjusted to a temperature of 150° C., leaving the other end to be free for 30 minutes, then measuring the distance between the target points at room temperature, taking this length as L (mm), and using this measured values.

150° C. thermal shrinkage(%)=100×(300−L)/300

In addition, a case where the thermal shrinkage is positive denotes shrinkage, and a case where the thermal shrinkage is negative denotes stretching.

As described above, according to the production method of the present invention as described above, a film having excellent hydrolysis resistance can be fabricated. The polyethylene terephthalate film of the present invention can be appropriately used not only as a protective sheet (back sheet) for a solar cell module as described below, but also in other applications.

In addition, the film of the present invention can also be used as a laminate including a coating layer containing at least one functional group selected from COOH, OH, SO₃H, NH₂, and a salt thereof thereon. The film of the present invention has excellent adhesiveness to a layer having the functional group as described above, from the viewpoint of including the polymer synthesized in the synthesis step.

[Back Sheet for Solar Cell Module]

The back sheet for a solar cell module of the present invention may include the polyethylene terephthalate film of the present invention.

The back sheet for a solar cell of the present invention may have the following functional layer applied to the polyester film by coating after uniaxial stretching and/or after biaxial stretching. For the application, known coating techniques such as a roll coating method, a knife edge coating method, a gravure coating method, a curtain coating method, and the like can be used.

In addition, a surface treatment (a flame treatment, a corona treatment, a plasma treatment, an ultraviolet treatment, and the like) may also be carried out before such the application. Further, bonding using an adhesive is also preferred.

Readily Adhesive Layer

In the polyester film of the present invention, a readily adhesive layer is preferably provided on the side facing the sealing material of the battery-side substrate, in which a photovoltaic cell is sealed with a sealing agent in the case of constituting the solar cell module. By providing a readily adhesive layer exhibiting adhesiveness to an adherend (for example, the surface of the battery-side substrate and the sealing agent, in which the photovoltaic cell is sealed with a sealing material) including a sealing agent (in particular, an ethylene-vinyl acetate copolymer), it is possible to adhere firmly between the back sheet and the sealing material. Specifically, the readily adhesive layer preferably has an adhesion power, in particular with EVA (an ethylene-vinyl acetate copolymer) used as a sealing material, of 10 N/cm or more, and preferably 20 N/cm or more.

In addition, Further, for the readily adhesive layer, it is required that peeling of the back sheet should not occur during the use of the solar cell module, and thus, it is preferable the readily adhesive layer have high wet heat resistance.

(1) Binder

The readily adhesive layer according to the present invention can contain at least one binder.

As the binder, a polyester, a polyurethane, an acrylic resin, a polyolefin, or the like can be used. Among these, from the viewpoint of durability, an acrylic resin and polyolefin are preferred. Further, as the acrylic resin, a composite resin of an acryl and a silicone is also preferred. Preferred examples of the binder include the following compounds.

Examples of the polyolefin include CHEMIPEARL S-120 and CHEMIPEARL S-75N (both manufactured by Mitsui Chemicals, Inc.). Examples of the acrylic resin include JURYMER ET-410 and JURYMER SEK-301 (both manufactured by Nihon Junyaku Co., Ltd.). Furthermore, examples of the composite resin of an acryl and a silicone include CERANATE WSA1060 and CERANATE WSA1070 (both manufactured by DIC Corp.), and H7620, H7630, and H7650 (all manufactured by Asahi Kasei Chemicals Corp.).

The amount of the binder is preferably in the range of from 0.05 g/m² to 5 g/m², and particularly preferably in the range of from 0.08 g/m² to 3 g/m². When the amount of the binder is 0.05 g/m² or more, a more satisfactory adhesive power is obtained, and when the amount of the binder is 5 g/m² or less, a more good surface shape is obtained.

(2) Fine Particles

The readily adhesive layer in the present invention can contain at least one kind of fine particles. The readily adhesive layer preferably contains the fine particles in an amount of 5% by mass or more with respect to the total mass of the layer.

Suitable examples of the fine particles include inorganic fine particles of silica, calcium carbonate, magnesium oxide, magnesium carbonate, tin oxide, and the like. Particularly among these, from the viewpoint that a decrease in the adhesiveness is small when exposed to a high-temperature and high-humidity atmosphere, fine particles of tin oxide and silica are preferred.

The particle diameter of the fine particles is preferably about 10 nm to 700 nm, and more preferably about 20 nm to 300 nm. When fine particles having a particle diameter in the range described above are used, satisfactory high adhesiveness can be obtained. There are no particular limitations on the shape of the fine particles, but fine particles having a spherical shape, an indefinite shape, a needle-like shape, and the like can be used.

The amount of the fine particles to be added in the readily adhesive layer is preferably from 5% by mass to 400% by mass, and more preferably from 50% by mass to 300% by mass, with respect to the binder in the readily adhesive layer. When the amount of the fine particles to be added is from 5% by mass or more, the adhesiveness when the readily adhesive layer is exposed to a high-temperature and high-humidity atmosphere is excellent. When the amount to be added is 1000% by mass or less, the surface shape of the readily adhesive layer is better.

(3) Crosslinking Agent

The readily adhesive layer in the present invention can contain at least one crosslinking agent.

Examples of the crosslinking agent include an epoxy-based crosslinking agent, an isocyanate-based crosslinking agent, a melamine-based crosslinking agent, a carbodiimide-based crosslinking agent, an oxazoline-based crosslinking agent, and the like. From the viewpoint of securing the adhesiveness after a lapse of time in a high-temperature and high-humidity atmosphere, among these crosslinking agents, an oxazoline-based crosslinking agent is particularly preferred.

Specific examples of the oxazoline-based crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane) sulfide, bis-(2-oxazolinylnorbornane) sulfide, and the like. In addition, (co)polymers of these compounds can also be preferably used.

Furthermore, as a compound having an oxazoline group, EPOCROS K2010E, EPOCROS K2020E, EPOCROS K2030E, EPOCROS WS500, and EPOCROS WS700 (all manufactured by Nippon Shokubai Co., Ltd.), and the like can also be used.

A preferable amount of the crosslinking agent to be added in the readily adhesive layer is preferably from 5% by mass to 50% by mass, and more preferably from 20% by mass to 40% by mass, with respect to the binder in the readily adhesive layer. When the amount of the crosslinking agent to be added is 5% by mass or more, a good crosslinking effect is obtained, and a decrease in the strength of the reflective layer or adhesion failure does not easily occur. When the amount of the crosslinking agent to be added is 50% by mass or less, the pot life of the coating liquid can be maintained longer.

(4) Additives

To the readily adhesive layer in the present invention, a known mat agent such as polystyrene, polymethyl methacrylate, silica, and the like; a known surfactant such as an anionic surfactant, a nonionic surfactant, and the like; etc. may also be further added, if desired.

(5) Method for Forming Readily Adhesive Layer

Examples of the method for forming the readily adhesive layer of the present invention include a method of bonding a polymer sheet having high adhesiveness to the polyester film, and a method based on coating. A method based on coating is preferred from the viewpoints of being convenient and capable of forming a highly uniform thin film. As the coating method, for example, a known method of using a gravure coater, a bar coater, and the like can be used. The solvent for the coating liquid that is used for coating may be water, or an organic solvent such as toluene and methyl ethyl ketone. The solvents may be used singly or as a mixture of two or more kinds thereof.

In addition, in the case of forming a readily adhesive layer by coating, the production method of the present invention preferably includes both of drying of the coating layer in a drying zone after the heat treatment as described above, and a heat treatment. Further, a case of forming the colored layer as described later or the other functional layers by coating is also preferred.

(6) Physical Properties of Readily Adhesive Layer

The thickness of the readily adhesive layer in the present invention is not particularly limited, but usually, the thickness is preferably from 0.05 μm to 8 μm, and more preferably in the range of from 0.1 μm to 5 μm. When the thickness of the readily adhesive layer is 0.05 μm or more, the high adhesiveness that is needed can be easily obtained, and when the thickness is 8 μm or less, the surface shape can be maintained more satisfactorily.

Furthermore, the readily adhesive layer in the present invention is preferably transparent from the viewpoint that when a colored layer (particularly a reflective layer) is arranged between the readily adhesive layer and the polyester film, the readily adhesive layer does not impair the effect of the colored layer.

Colored Layer

The polyester film of the present invention can be provided with a colored layer. The colored layer is a layer arranged to be in contact with the surface of the polyester film or with another layer interposed therebetween, and can be constructed using a pigment or a binder.

A first function of the colored layer is to increase the power generation efficiency of a solar cell module by reflecting a portion of light in the incident light, which is not used in the power generation at the photovoltaic cell and reaches the back sheet, and returning the portion of light to the photovoltaic cell. A second function is to enhance the decorative properties of the external appearance when the solar cell module is viewed from the front surface side. Generally, when a solar cell module is viewed from the front surface side, the back sheet is seen around the photovoltaic cell. Thus, the decorative properties can be increased by providing a colored layer to the back sheet.

(1) Pigment

The colored layer in the present invention can contain at least one pigment. The pigment is preferably included in an amount in the range of from 2.5 g/m² to 8.5 g/m². A more preferred pigment content is in the range of from 4.5 g/m² to 7.5 g/m². When the pigment content is 2.5 g/m² or more, necessary coloration can be easily obtained, and the light reflectivity or decorative properties can be further improved. When the pigment content is 8.5 g/m² or less, the surface shape of the colored layer can be maintained more satisfactorily.

Examples of the pigment include inorganic pigments such as titanium oxide, barium sulfate, silicon oxide, aluminum oxide, magnesium oxide, calcium carbonate, kaolin, talc, ultramarine blue, Prussian blue, carbon black, and the like; and organic pigments such as phthalocyanine blue, phthalocyanine green, and the like. Among these pigments, a white pigment is preferable from the viewpoint of constituting the colored layer as a reflective layer that reflects sunlight incident thereon. Preferred examples of the white pigment include titanium oxide, barium sulfate, silicon oxide, aluminum oxide, magnesium oxide, calcium carbonate, kaolin, talc, and the like.

The average particle diameter of the pigment is preferably from 0.03 μm to 0.8 μm, and more preferably from about 0.15 μm to 0.5 μm. When the average particle diameter is in the range described above, the light reflection efficiency may be lowered.

In the case of constructing the colored layer as a reflective layer that reflects sunlight that has entered, the preferable amount of the pigment to be added in the reflective layer varies with the type or average particle diameter of the pigment used and cannot be defined briefly. However, the amount of the pigment to be added is preferably from 1.5 g/m² to 15 g/m², and more preferably from about 3 g/m² to 10 g/m². When the addition amount thereof is 1.5 g/m² or more, a necessary reflectance can be easily obtained, and when the addition amount thereof is 15 g/m² or less, the strength of the reflective layer can be maintained at a higher level.

(2) Binder

The colored layer in the present invention can contain at least one binder. When the colored layer contains a binder, the amount of the binder is preferably in the range of from 15% by mass to 200% by mass, and more preferably in the range of from 17% by mass to 100% by mass, with respect to the pigment. When the amount of the binder is 15% by mass or more, the strength of the colored layer can be maintained more satisfactorily, and when the amount is 200% by mass or less, the reflectance or decorative properties is lowered.

As the binder suitable for the colored layer, a polyester, a polyurethane, an acrylic resin, a polyolefin, or the like can be used. The binder is preferably an acrylic resin or a polyolefin from the viewpoint of durability. As an acrylic resin, a composite resin of an acryl and a silicone is also preferred. Preferred examples of the binder include the following compounds.

Examples of the polyolefin include CHEMIPEARL S-120 and CHEMIPEARL S-75N (both manufactured by Mitsui Chemicals, Inc.), and the like. Examples of the acrylic resin include JURYMER ET-410 and JURYMER SEK-301 (both manufactured by Nihon Junyaku Co., Ltd.), and the like. Furthermore, examples of the composite resin of an acryl and a silicone include CERANATE WSA1060 and CERANATE WSA1070 (both manufactured by DIC Corp.), H7620, H7630, and H7650 (all manufactured by Asahi Kasei Chemicals Corp.), and the like.

(3) Additives

To the colored layer in the present invention, a crosslinking agent, a surfactant, a filler, or the like may also be further added, if desired, in addition to the binder and the pigment.

Examples of the crosslinking agent include an epoxy-based crosslinking agent, an isocyanate-based crosslinking agent, a melamine-based crosslinking agent, a carbodiimide-based crosslinking agent, an oxazoline-based crosslinking agent, and the like. The amount of the crosslinking agent to be added in the colored layer is preferably from 5% by mass to 50% by mass, and more preferably from 10% by mass to 40% by mass, with respect to the binder in the colored layer. When the amount of the crosslinking agent to be added is 5% by mass or more, a good crosslinking effect is obtained, and the strength or adhesiveness of the colored layer can be maintained at a high level. When the amount of the crosslinking agent to be added is 50% by mass or less, the pot life of the coating liquid can be maintained longer.

As the surfactant, a known surfactant such as an anionic surfactant, a nonionic surfactant, and the like can be used. The amount of the surfactant to be added is preferably from 0.1 mg/m² to 15 mg/m², and more preferably from 0.5 mg/m² to 5 mg/m². When the amount of the surfactant to be added is 0.1 mg/m² or more, generation of cissing can be effectively suppressed, and when the addition amount thereof is 15 mg/m² or less, excellent adhesiveness is obtained.

Furthermore, the colored layer may also contain a filler such as silica and the like, in addition to the pigments described above. The amount of the filler to be added is preferably 20% by mass or less, and more preferably 15% by mass or less, with respect to the binder in the colored layer. When the colored layer contains a filler, the strength of the colored layer can be increased. Furthermore, when the amount of the filler to be added is 20% by mass or less, the proportion of the pigment can be retained, and therefore, satisfactory light reflectivity (reflectance) or decorative properties are obtained.

(4) Method for Forming Colored Layer

Examples of the method for forming the colored layer include a method of bonding a polymer sheet containing a pigment on the polyester film, a method of co-extruding the colored layer during the molding of the polyester film, and a method based on coating. Among these, the method based on coating is preferred from the viewpoint of being convenient and capable of forming a highly uniform thin film. As the coating method, for example, a known method of using a gravure coater or a bar coater can be used. The solvent for the coating liquid used in the coating may be water, or may be an organic solvent such as toluene, methyl ethyl ketone, and the like. However, from the viewpoint of environmental burden, it is preferable to use water as the solvent.

The solvents may be used singly or as a mixture of two or more kinds thereof.

(5) Physical Properties of Colored Layer

It is preferable that the colored layer contain a white pigment and is constructed as a white layer (light reflective layer). In the case where the colored layer is a reflective layer, the light reflectance for light at 550 nm is preferably 75% or more. When the reflectance is 75% or more, the portion of sunlight that passes through the photovoltaic cell and is not used in power generation can be returned to the cell, and a large effect of increasing the power generation efficiency is obtained.

The thickness of the white layer (light reflective layer) is preferably from 1 μm to 20 μm, more preferably from 1 μm to 10 μm, and even more preferably from about 1.5 μm to 10 μm. When the thickness is 1 μm or more, necessary decorative properties or a reflectance can be easily obtained, and when the thickness is more than 20 μm, the surface shape may be deteriorated in some cases.

Undercoat Layer

The polyester film in the present invention can be provided with an undercoat layer. For example, when a colored layer is provided, the undercoat layer may be provided between the colored layer and the polyester film. The undercoat layer can be constructed by using a binder, a crosslinking agent, a surfactant, or the like.

Examples of the binder contained in the undercoat layer include polyester, polyurethane, an acrylic resin, a polyolefin, and the like. To the undercoat layer, crosslinking agents such as an epoxy-based crosslinking agent, an isocyanate-based crosslinking agent, a melamine-based crosslinking agent, a carbodiimide-based crosslinking agent, an oxazoline-based crosslinking agent, and the like; surfactants such as an anionic surfactant, a nonionic surfactant, and the like; a filler such as silica and the like; etc. may be added, in addition to the binder.

There are no particular limitations on the method for coating and forming the undercoat layer, or the solvent for the coating liquid used in the method.

As the coating method, for example, a gravure coater or a bar coater can be used. The solvent may be water, or may be an organic solvent such as toluene, methyl ethyl ketone, and the like. The solvents may be used singly or as a mixture of two or more kinds thereof.

Coating may be carried out such that the undercoat layer may be applied on a polyester film obtained after biaxial stretching, or may be applied on a polyester film obtained after uniaxial stretching. In this case, the polyester film may be further stretched, after applying the undercoat layer, in the direction different from the direction of initial stretching. Furthermore, the undercoat layer may be applied on a polyester film prior to stretching, and then the polyester film may be stretched in two directions.

The thickness of the undercoat layer is preferably from 0.05 μm to 2 μm, and more preferably in the range of from about 0.1 μm to 1.5 μm. When the film thickness of the layer is 0.05 μm or more, necessary adhesiveness can be easily obtained, and when the thickness is 2 μm or less, the surface shape can be maintained satisfactorily.

Antifouling Layer (Fluorine-Based Resin Layer and Silicon-Based Resin Layer)

The polyester film of the present invention is preferably provided with at least one of a fluorine-based resin layer and a silicon-based (Si-based) resin layer as an antifouling layer. When a fluorine-based resin layer or a Si-based resin layer is provided, prevention of contamination of the polyester surface and an enhancement of weather resistance can be promoted. Specifically, it is preferable that the polyester film have a fluorine resin-based coating layer such as those described in JP-A-2007-35694 and JP-A-2008-28294, and WO 2007/063698.

Furthermore, it is also preferable that a fluorine-based resin film such as TEDLAR (manufactured by DuPont Company) be adhered to the polyester film.

The thicknesses of the fluorine-based resin layer and the Si-based resin layer are respectively preferably in the range of from 1 μm to 50 μm, more preferably in the range of from 1 μm to 40 μm, and even more preferably from 1 μm to 10 μm.

[Solar Cell Module]

The solar cell module of the present invention may include the polyester film or the back sheet of the present invention.

The solar cell module of the present invention is constituted such that a photovoltaic cell that converts the light energy of sunlight to electrical energy be arranged between a transparent substrate, on which sunlight is incident, and the polyester film (back sheet for a solar cell) of the present invention. The space between the substrate and the polyester film can be configured to be sealed with a resin (a so-called sealing material) such as an ethylene-vinyl acetate copolymer and the like.

The details of the solar cell module, the photovoltaic cell, and the members other than the back sheet are described in, for example, “Constituent Materials for Photovoltaic Power Generation System” (edited by Eiichi Sugimoto, Kogyo Chosakai Publishing Co., Ltd. published in 2008).

The transparent substrate may desirably have light transmitting properties by which sunlight can be transmitted, and can be appropriately selected from base materials that transmit light. From the viewpoint of power generation efficiency, a base material having higher light transmittance is preferable, and as such a substrate, for example, a glass substrate, a substrate of a transparent resin such as an acrylic resin and the like, etc. can be suitably used.

As the photovoltaic cell, various known photovoltaic cells such as silicon-based elements such as single crystal silicon, polycrystalline silicon, amorphous silicon, and the like; Group III-V or Group II-VI compound semiconductor-based elements such as copper-indium-gallium-selenium, copper-indium-selenium, cadmium-tellurium, gallium-arsenic, and the like; etc. may be applied.

### EXAMPLES

Hereinafter, the present invention will be described in more detail with reference to the following Examples. In Examples as described below, the material, the amounts and ratios thereof, the details of the treatment, the treatment procedure, and the like may be suitably modified within a range not departing from the spirit of the present invention. Therefore, the range of the present invention should not be construed to be limited by the Examples as described below. Unless otherwise specifically indicated, the “part(s)” is on the basis of mass.

### Example 1

### <1> Synthesis of Polyethylene Terephthalate

Step (A)

4.7 tons of high-purity terephthalic acid and 1.8 tons of ethylene glycol were mixed over 90 minutes to form a slurry, and the slurry was continuously supplied to a first esterification reaction tank at a flow rate of 3800 kg/h. Subsequently, an ethylene glycol solution of a citric acid chelated titanium complex (VERTEC AC-420, manufactured by Johnson Matthey Plc.) having Ti metal coordinated with citric acid was continuously supplied, to a first esterification reaction tank and a reaction was carried out at a temperature inside the reaction tank of 250° C. and for an average retention time of about 4.3 hours with stirring, thereby obtaining an oligomer. At this time, the citric acid chelated titanium complex was continuously added such that the addition amount of Ti was 9 ppm in terms of elements. At this time, the acid value of the oligomer thus obtained was 550 eq/ton.

The obtained oligomer was transferred to a second esterification reaction tank, and with stirring, the reaction product was allowed to react at a temperature inside the reaction tank of 250° C. for an average retention time of 1.2 hours to obtain an oligomer having an acid value of 180 eq/ton. The inside of the second esterification reaction tank was divided into three zones ranging a first zone to a third zone. At a second zone, an ethylene glycol solution of magnesium acetate was continuously supplied in a manner that the addition amount of Mg was 75 ppm in terms of elements. After that, at a third zone, an ethylene glycol solution of trimethyl phosphate was continuously supplied in a manner that the addition amount of P was 65 ppm in terms of elements. Further, the ethylene glycol solution of trimethyl phosphate was prepared by adding a trimethyl phosphate solution at 25° C. to an ethylene glycol solution at 25° C., followed by stirring at 25° C. for 2 hours (content of phosphorous compounds in the solution: 3.8% by mass).

Thus, an esterification reaction product was obtained.

Step (B)

The esterification reaction product obtained in the step (A) was continuously supplied to a first polycondensation reaction tank.

Subsequently, polycondensation (transesterification reaction) was carried out with stirring the esterification reaction product at a reaction temperature of 270° C. and a pressure inside the reaction tank of 20 torr (2.67×10⁻³ MPa) for an average retention time of about 1.8 hours.

Then, the obtained reaction product was transferred from the first polycondensation reaction tank to a second polycondensation reaction tank, and in this reaction tank, a reaction (transesterification reaction) was carried out with stirring under the conditions of a temperature inside the reaction tank of 276° C. and a pressure inside the reaction tank of 5 torr (6.67×10⁻⁴ MPa) for a retention time of about 1.2 hours.

Subsequently, the reaction product obtained by the transesterification reaction was transferred from the second polycondensation reaction tank to a third polycondensation reaction tank, and in this reaction tank, a reaction (transesterification reaction) was carried out with stirring under the conditions of a temperature inside the reaction tank of 278° C. and a pressure inside the reaction tank of 1.5 torr (2.0×10⁻⁴ MPa) for a retention time of 1.5 hours to obtain a reaction product (polyethylene terephthalate) having a carboxylic acid value of 24 eq/ton and an IV (intrinsic viscosity) of 0.63 dl/g.

Step (C)

The resin was dried at 170° C. for 5 hours, and then the pellet was transferred to a solid-phase polymerization tank and subjected to solid-phase polymerization in a solid-phase polymerization tank while flowing an N₂ gas containing 200 ppm of water vapor at 1 Nm³/hr per kg of resin at 210° C. Further, by changing the solid-phase polymerization time and the concentration of the ethylene glycol (EG) gas blown into the N₂ gas, a polyethylene terephthalate resin having an intrinsic viscosity of 0.78 dl/g, a carboxylic acid value of 12 eq/ton, and a melting point of 255° C. was obtained.

The obtained polyethylene terephthalate resin was taken as a polyethylene terephthalate 1.

In addition, by increasing the solid-phase polymerization time, the AV is lowered and the IV is increased. Further, by increasing the EG gas, the AV can be lowered. Further, IV is not affected.

### <2> Fabrication of Resin Composition (Master Pellet) of the Present Invention

Extrusion-Molding (Synthesis Step/Film Forming Step)

90.0 parts by mass of polyethylene terephthalate 1 that has been subjected to solid-phase polymerization by the method was mixed with 10.0 parts by mass of STABAXOL P400 (a polycarbodiimide compound having a weight average molecular weight of 26000, manufactured by Rhein Chemie Japan Ltd.) shown in Table 1 to prepare a master pellet as an end capping agent.

Specifically, the master pellet was prepared using the double-screw kneading extruder shown in FIG. 1. That is, a PET resin was added from a hopper, and an end capping agent of powder was kneaded by metering and introducing it from the hopper using a feeder. The kneaded composition was extruded into a strand shape, then cooled with water, and cut to produce a master pellet that is the polyethylene terephthalate resin composition of Example 1.

In the double-screw kneading extruder used in Example 1, the first barrel to the eighth barrel were arranged at equal intervals.

In the first barrel to the eighth barrel, a double-screw screw having a total length, L=2300 mm and a diameter D=40 mm was installed.

The C1 barrel to which the end capping agent of the double-screw kneading extruder and the polyethylene terephthalate resin are supplied was set to 90° C., the C2 barrel temperature was set to 100° C., the C3 to C5 barrel temperatures were set to 270° C., the C6 to C7 barrel temperatures were set to 240° C., and the C8 barrel temperature was set to 270° C.

In addition, each of the temperatures of the respective barrels is a value measured by a temperature sensor installed near the inner wall of a cylinder in the central portion of the zone length of each barrel.

Measurement of Physical Properties of Pellet of Resin Composition

(Decomposition Rate of Carbodiimide)

A sample obtained by mixing powder formed by pulverizing polyethylene terephthalate and powder formed by pulverizing polycarbodiimide at an arbitrary ratio was subjected to infrared spectrometry, and a calibration curve of the amount of polycarbodiimide in polyethylene terephthalate was produced from the peak intensity at 2140 cm⁻¹ and 2960 cm⁻¹.

The sample from pulverization of the resin compositions (master pellet) produced by Examples was subjected to infrared spectrometry, the amount of polycarbodiimide in polyethylene terephthalate was calculated, and the decomposition rate with respect to the amount of polycarbodiimide used was evaluated. The obtained results are shown in Table 1 below.

### <3> Formation of Polyethylene Terephthalate Film (Biaxially Stretched Film)

The master pellet of the obtained polyethylene terephthalate resin composition in Example 1 was dried to a water content of 100 ppm or less, and then mixed and extruded using the same polyethylene terephthalate 1 as in the fabrication of the master pellet such that the content of the polycarbodiimide with respect to the total resin composition became 0.4% by mass, thereby obtaining an unstretched film. Further, the amount of the end capping agent to be added as mentioned herein refers to % by mass with respect to the polyethylene terephthalate resin. Further, while melt-kneading at 280° C. under a nitrogen gas flow using a double-screw extruder for extrusion, this melt was extruded on a chill roll through a gear pump, a filter, and a die, thereby fabricating an unstretched film having a thickness of 2685 μm and a width of 483 mm.

This unstretched film was heated by a radiation heater until the temperature of the film surface reached about 85° C., then heated, and stretched by 3.4 times in the length direction. Subsequently, the film was transferred to a tenter and heated until the temperature of the film surface reached about 140° C., then heated, and stretched by 4.2 times in the vertical direction, thereby obtaining a biaxially stretched film having a thickness of 188 μm and a width of 1100 mm, which was taken as a polyethylene terephthalate film of Example 1.

Process Evaluation

(Gas)

Sensory evaluation of the smoke and the smell generated from a die of a double-screw extruder was carried out, and the volatilization was evaluated based on the following criteria. The obtained results are shown in Table 1 below.

<Criteria>

B: There was no occurrence of smoke and smell.

C: There was no occurrence of smoke but there was occurrence of smell.

D: There was occurrence of smoke and smell.

(Variation in Film Thickness)

The variation in the film thickness of polyethylene terephthalate film when film formation was continuously carried out for 4 hours was evaluated. The obtained results are shown in Table 1 below.

A: The variation in the film thickness is within 5%.

B: The variation in the film thickness is from 5% to 8%.

C: The variation in the film thickness is from 8% to 10%.

D: The variation in the film thickness is more than 10%.

Measurement of Physical Properties of Biaxially Stretched Film

(Surface Shape)

The obtained polyethylene terephthalate film was visually observed, and the surface shape was visually evaluated according to the following criteria. The obtained results are shown in Table 1 below.

<Criteria>

B: Wrinkles or foreign materials were not perceived and the surface shape was good.

C: Some wrinkles or foreign materials were partially perceived.

D: Wrinkles or foreign materials were perceived.

(Hydrolysis Resistance Performance (PCT Test))

When the obtained polyethylene terephthalate film was subjected to a wet heat treatment (thermo-treatment under the conditions of 120° C. and a relative humidity of 100%), the time at which the retention rate of tensile elongation at break before and after the treatment was 50% was evaluated. The tensile test was based on JIS K 7127.

Retention rate of tensile elongation at break[%]=(Elongation at break after thermo-treatment)/(Elongation at break before thermo-treatment)×100

The obtained results are shown in Table 1 below. Further, the time at which the retention rate of tensile elongation at break was 50% is required to be 180 hours or more, preferably 190 hours or more, and more preferably 200 hours or more in practical use.

(Heat Resistance)

The obtained polyethylene terephthalate film was subjected to a heat treatment at 150° C. for 48 hours, to afford a polyethylene terephthalate film for evaluation of heat resistance. The maximum strength of the polyethylene terephthalate film for evaluation of heat resistance was taken as S (MPa) and the maximum strength after heat treatment at 180° C. for 120 hours was taken as T (MPa). The index R of heat resistance was calculated by the following calculation formula, and evaluated according to the following criteria. The obtained results are shown in Table 1 below.

R (%)=S/T×100

A: R (%) is 80% or more.

B: R (%) is from 60% to 80%.

D: R (%) is less than 60%.

### <4> Fabrication of Back Sheet

A back sheet for a solar cell was fabricated, using the polyethylene terephthalate film fabricated in Example 1.

First, on one surface of the polyethylene terephthalate film fabricated in Example 1, the following (i) reflective layer and (ii) readily adhesive layer were applied in this order by coating.

(i) Reflective Layer (Colored Layer)

All the components having the following composition were mixed and subjected to a dispersion treatment for 1 hour with a dyno-mill disperser, thereby preparing a pigment dispersion.

<Formulation of Pigment Dispersion>

| | | |
|---|---|---|
| Titanium dioxide (TIPAQUE R-780-2, manufactured by | 39.9 | parts |
| Ishihara Sangyo Kaisha, Ltd., 100% by mass of solid | | |
| content) | | |
| Polyvinyl alcohol (PVA-105, manufactured by Kuraray | 8.0 | parts |
| Co., Ltd., 10% of solid content) | | |
| Surfactant (DEMOL EP, manufactured by Kao Corp., | 0.5 | parts |
| 25% of solid content) | | |
| Distilled water | 51.6 | parts |

Then, using the obtained pigment dispersion, the components having the following composition were mixed to prepare a coating liquid for forming a reflective layer.

<Formulation of Coating Liquid for Forming Reflective Layer>

| | | |
|---|---|---|
| Pigment dispersion above | 71.4 | parts |
| Polyacrylic resin water dispersion (binder: JURYMER | 17.1 | parts |
| ET410, manufactured by Nihon Junyaku Co., Ltd., 30% | | |
| by mass of solid content) | | |
| Polyoxyalkylene alkyl ether (NAROACTY CL95, | 2.7 | parts |
| manufactured by Sanyo Chemical Industries, Ltd., 1% | | |
| by mass of solid content) | | |
| Oxazoline compound (cross-linking agent) (EPOCROS | 1.8 | parts |
| WS-700, manufactured by NIPPON SHOKUBAI Co., Ltd., | | |
| 25% by mass of solid content) | | |
| Distilled water | 7.0 | parts |

The coating liquid for forming a reflective layer obtained above was coated on the polyethylene terephthalate film of Example 1 by a bar coater, and dried at 180° C. for 1 minute, thereby forming a (i) reflective layer (white layer) having a titanium dioxide coating amount of 6.5 g/m².

(ii) Readily Adhesive Layer

All of the components with the following composition were mixed to prepare a coating liquid for a readily adhesive layer. The coating liquid was coated to a binder coating amount of binder of 0.09 g/m² onto the (i) reflective layer, and then dried at 180° C. for 1 minute to form (ii) a readily adhesive layer.

<Composition of Coating Liquid for Forming Readily Adhesive Layer>

| | | |
|---|---|---|
| Polyolefin resin water dispersion (carboxylic- | 5.2 | parts |
| containing binder: CHEMIPEARL S75N, manufactured | | |
| by Mitsui chemicals, Inc., 24% by mass of solid content) | | |
| Polyoxyalkylene alkyl ether (NAROACTY CL95, | 7.8 | parts |
| manufactured by Sanyo Chemical Industries, Ltd., 1% | | |
| by mass of solid content) | | |
| Oxazoline compound (EPOCROS WS-700, | 0.8 | parts |
| manufactured by NIPPON SHOKUBAI Co., Ltd., 25% | | |
| by mass of solid content) | | |
| Silica fine particle water dispersion (AEROSIL OX- | 2.9 | parts |
| 50, manufactured by Nippon Aerosil Co., Ltd., 10% | | |
| by mass of solid content) | | |
| Distilled water | 83.3 | parts |

Next, on the surface side opposite to the side having (i) the reflective layer and (ii) the readily adhesive layer of the polyethylene terephthalate film formed thereon, the following (iii) undercoat layer, (iv) barrier layer, and (v) antifouling layer were applied by coating successively from the polyethylene terephthalate film side.

(iii) Undercoat Layer

All of the components with the following composition were mixed to prepare a coating liquid for forming an undercoat layer. This coating liquid was coated on the polyethylene terephthalate film and dried at 180° C. for one minute to form an undercoat layer (dried coating amount: about 0.1 g/m²).

<Composition of Coating Liquid for Forming Undercoat Layer>

| | | |
|---|---|---|
| Polyester resin (VYLONAL MD-1200, manufactured by | 1.7 | parts |
| TOYOBO Co., Ltd., 17% by mass of solid content) | | |
| Polyester resin (sulfonic acid-containing binder: | 3.8 | parts |
| PESRESIN A-520, manufactured by TAKAMATSU | | |
| OIL&FAT Co., Ltd., 30% by mass of solid content) | | |
| Polyoxyalkylene alkyl ether (NAROACTY CL95, | 1.5 | parts |
| manufactured by Sanyo Chemical Industries, Ltd., 1% | | |
| by mass of solid content) | | |
| Carbodiimide compound (CARBODILITE V-02-L2, | 1.3 | parts |
| manufactured by Nisshinbo Industries, Inc., 10% by | | |
| mass of solid content) | | |
| Distilled water | 91.7 | parts |

(iv) Barrier Layer

Subsequently, on the surface of thus formed undercoat layer, an 800 angstroms thick vacuum deposition film of silicon oxide was formed under the following vacuum deposition conditions. The film served as a barrier layer.

<Vacuum Deposition Conditions>
Reactive gas mixing ratio (unit:slm):hexamethyl disiloxane/oxygen gas/helium=1/10/10
Vacuum degree inside vacuum chamber: 5.0×10⁻⁶ mbar
Vacuum degree inside deposition chamber: 6.0×10⁻² mbar
Electric power supplied to cooling and electrode drums: 20 kW
Film conveying speed: 80 m/minute

(v) Antifouling Layer

As shown below, coating liquids for forming a first antifouling layer and a second antifouling layer were prepared. The coating liquid for forming the first antifouling layer and the coating liquid for forming the second antifouling layer were coated in this order on the barrier layer, so that an antifouling layer having a bi-layer structure was applied by coating.

<First Antifouling Layer>

Preparation of Coating Liquid for Forming First Antifouling Layer

The components with the following composition were mixed to prepare a coating liquid for forming the first antifouling layer.

<Composition of Coating Liquid>

| | | |
|---|---|---|
| CERANATE WSA1070 (manufactured by DIC Corp.) | 45.9 | parts |
| Oxazoline compound (cross-linking agent) (EPOCROS | 7.7 | parts |
| WS-700, manufactured by NIPPON SHOKUBAI Co., | | |
| Ltd., 25% by mass of solid content) | | |
| Polyoxyalkylene alkyl ether (NAROACTY CL95, | 2.0 | parts |
| manufactured by Sanyo Chemical Industries, Ltd., 1% | | |
| by mass of solid content) | | |
| Pigment dispersion used for the reflective layer | 33.0 | parts |
| Distilled water | 11.4 | parts |

Formation of First Antifouling Layer

The obtained coating liquid was coated on the barrier layer to a binder coating amount of 3.0 g/m², and dried at 180° C. for 1 minute to form the first antifouling layer.

Preparation of Coating Liquid for Forming Second Antifouling Layer

The components with the following composition were mixed to prepare a coating liquid for forming the second antifouling layer.

<Composition of Coating Liquid>

| | | |
|---|---|---|
| Obbligato SW0011F (fluorobinder, manufactured by | 45.9 | parts |
| AGC Coat-tech) | | |
| Oxazoline compound (EPOCROS WS-700, | 7.7 | parts |
| manufactured by NIPPON SHOKUBAI Co., Ltd., 25% | | |
| by mass of solid content) | | |
| Polyoxyalkylene alkyl ether (NAROACTY CL95, | 2.0 | parts |
| manufactured by Sanyo Chemical Industries, Ltd., 1% | | |
| by mass of solid content) | | |
| Pigment dispersion used for the reflective layer | 33.0 | parts |
| Distilled water | 11.4 | parts |

Formation of Second Antifouling Layer

The obtained coating liquid for forming the second antifouling layer was coated on the first antifouling layer formed on the barrier layer to a binder coating amount of 2.0 g/m², and dried at 180° C. for 1 minute to form the second antifouling layer.

As described above, the back sheet for a solar cell module of Example 1, which has a reflective layer and readily adhesive layer on one side of the polyethylene terephthalate film, and has an undercoat layer, a barrier layer, and an antifouling layer on the other side, was fabricated.

(Adhesion after Wet Heat Aging)

The obtained back sheet for a solar cell module of Example 1, the adhesion after storage for 60 hours at 120° C. and a relative humidity of 100% was evaluated by a tape peeling test. The tape peeling test was carried out by putting a grid cut to allow the film reaching the surface layer of the polyester film from the surface layer of the side of the coating layer, and evaluated according to the following criteria. The results are shown in Table 1 below.

B: Not peeled.

C: Peeling of less than 10% was observed.

D: Peeling of 10% or more was observed.

### Examples 2 to 19 and Comparative Examples 1 to 7

In the same manner as in Example 1 except for carrying out the melt-kneading under the extruder and production conditions shown in Table 1, a resin composition (master pellet of an end capping agent) of each of Examples and Comparative Examples was produced. In Table 1 below STABILIZER 9000 is a polycarbodiimide compound having a weight average molecular weight of 20000, manufactured by Raschig GmbH, and HMV-8CA is a polycarbodiimide compound having a number average molecular weight of about 3000, manufactured by Nisshinbo Chemicals, Co. Further, PBT used in Comparative Examples 8 and 9 is the polybutylene terephthalate film described as PBT1 in JP-A-2002-194187.

Thereafter, in the same manner as in Example 1 except for using the resin composition of each of Examples and Comparative Examples as a master pellet of an end capping agent and using a pellet of the resin composition, formed by diluting the master pellet of an end capping agent, a polyethylene terephthalate film of each of Examples and Comparative Examples was produced.

In the same manner as in Example 1 except for using the obtained polyethylene terephthalate film of each of Examples and Comparative Examples, a back sheet for a solar cell module of each of Examples and Comparative Examples was fabricated.

In each of Examples and Comparative Examples, the results of evaluation carried out in the same manner as in Example 1 are shown in Table 1 below.

TABLE 1

| | Fabrication condition of master pellets | | | | | | | | |
|---|---|---|---|---|---|---|---|---|---|
| | | | | | | | Melt-kneading condition | | |
| | Composition of raw materials upon introduction | | | | | | | Maximum | Minimum |
| | Polyester | | | | Polycarbodiimide | | | temperature | temperature |
| | | melting | | Temperature | | Melting | | (° C.) | (° C.) |
| | | point | Water | (° C.) upon | | point | Screw | Tmax of | Tmin of |
| | Kind | (° C.) | content | introduction | Kind | (° C.) | rotations | barral | barrel |
| Example 1 | PET | 255 | 120 ppm | 160 | STABAXOL P400 | 150 | 170 rpm | 260 | 240 |
| Example 2 | PET | 255 | 120 ppm | 160 | STABAXOL P400 | 150 | 150 rpm | 260 | 240 |
| Example 3 | PET | 255 | 120 ppm | 160 | STABAXOL P400 | 150 | 100 rpm | 260 | 240 |
| Example 4 | PET | 255 | 120 ppm | 160 | STABAXOL P400 | 150 | 80 rpm | 260 | 240 |
| Example 5 | PET | 255 | 120 ppm | 160 | STABAXOL P400 | 150 | 150 rpm | 270 | 240 |
| Example 6 | PET | 255 | 120 ppm | 160 | STABAXOL P400 | 150 | 150 rpm | 250 | 240 |
| Example 7 | PET | 255 | 120 ppm | 160 | STABAXOL P400 | 150 | 150 rpm | 260 | 250 |
| Example 8 | PET | 255 | 120 ppm | 160 | STABAXOL P400 | 150 | 150 rpm | 260 | 200 |
| Example 9 | PET | 255 | 120 ppm | 160 | STABAXOL P400 | 150 | 150 rpm | 280 | 190 |
| Example 10 | PET | 255 | 120 ppm | 160 | STABAXOL P400 | 150 | 150 rpm | 280 | 240 |
| Example 11 | PET | 255 | 120 ppm | 160 | STABAXOL P400 | 150 | 150 rpm | 280 | 240 |
| Example 12 | PET | 255 | 120 ppm | 160 | STABAXOL P400 | 150 | 150 rpm | 280 | 240 |
| Example 13 | PET | 255 | 160 ppm | 160 | STABAXOL P400 | 150 | 150 rpm | 280 | 240 |
| Example 14 | PET | 255 | 150 ppm | 160 | STABAXOL P400 | 150 | 150 rpm | 260 | 240 |
| Example 15 | PET | 255 | 100 ppm | 160 | STABAXOL P400 | 150 | 150 rpm | 260 | 240 |
| Example 16 | PET | 255 | 120 ppm | 160 | STABAXOL P400 | 150 | 150 rpm | 260 | 240 |
| Example 17 | PET | 255 | 120 ppm | 160 | STABAXOL P400 | 150 | 100 rpm | 280 | 220 |
| Example 18 | PET | 255 | 120 ppm | 160 | STABILIZER | 150 | 150 rpm | 260 | 240 |
| | | | | | 9000 | | | | |
| Example 19 | PET | 255 | 80 ppm | 170 | STABAXOL P400 | 150 | 150 rpm | 260 | 240 |
| Comparative | PET | 255 | 120 ppm | 160 | STABAXOL P400 | 150 | 200 rpm | 275 | 240 |
| Example 1 | | | | | | | | | |
| Comparative | PET | 255 | 120 ppm | 160 | STABAXOL P400 | 150 | 180 rpm | 260 | 240 |
| Example 2 | | | | | | | | | |
| Comparative | PET | 255 | 120 ppm | 160 | STABAXOL P400 | 150 | 70 rpm | 260 | 240 |
| Example 3 | | | | | | | | | |
| Comparative | PET | 255 | 120 ppm | 160 | STABAXOL P400 | 150 | 150 rpm | 300 | 240 |
| Example 4 | | | | | | | | | |
| Comparative | PET | 255 | 120 ppm | 160 | STABAXOL P400 | 150 | 150 rpm | 280 | 240 |
| Example 5 | | | | | | | | | |
| Comparative | PET | 255 | 120 ppm | 160 | STABAXOL P400 | 150 | 150 rpm | 240 | 240 |
| Example 6 | | | | | | | | | |
| Comparative | PET | 255 | 120 ppm | 160 | STABAXOL P400 | 150 | 150 rpm | 260 | 240 |
| Example 7 | | | | | | | | | |
| Comparative | PET | 230 | 120 ppm | 160 | STABAXOL P400 | 150 | 160 rpm | 250 | 250 |
| Example 8 | | | | | | | | | |
| Comparative | PET | 250 | 120 ppm | 160 | HMV-8CA | 70 | 160 rpm | 250 | 250 |
| Example 9 | | | | | | | | | |

| | Fabrication | | | | | | | | |
|---|---|---|---|---|---|---|---|---|---|
| | condition of | | Evaluation | | | | | | |
| | master pellets | | | Flim forming | | | | | |
| | Melt-kneading | | Master | process | | | | | |
| | condition | | pellets | | Variation | | | | Back sheet |
| | C1 | | Carbodiimide | | of change | Polyethylene terephthalate film | | | Adhesion |
| | Temperature | Number | decomposition | | in | Surface | Hydrolysis | Heat | after wet |
| | (° C.) | of vents | rate | Gas | thickness | shape | resistance | resistance | heat aging |
| Example 1 | 90 | 2 | 25 | B | A | B | 190 hours | B | B |
| Example 2 | 90 | 2 | 20 | B | A | B | 200 hours | B | B |
| Example 3 | 90 | 2 | 15 | B | A | B | 200 hours | B | B |
| Example 4 | 90 | 2 | 20 | B | A | B | 200 hours | B | B |
| Example 5 | 90 | 2 | 25 | B | A | B | 190 hours | B | B |
| Example 6 | 90 | 2 | 20 | B | A | B | 200 hours | B | B |
| Example 7 | 90 | 2 | 35 | B | B | B | 180 hours | B | B |
| Example 8 | 90 | 2 | 20 | B | A | B | 200 hours | B | B |
| Example 9 | 90 | 2 | 15 | B | A | C | 200 hours | B | B |
| Example 10 | 120 | 2 | 20 | B | A | B | 200 hours | B | B |
| Example 11 | 150 | 2 | 20 | B | A | C | 180 hours | B | B |
| Example 12 | 50 | 2 | 20 | B | A | B | 200 hours | B | B |
| Example 13 | 90 | 2 | 20 | B | B | B | 180 hours | B | B |
| Example 14 | 90 | 2 | 20 | B | A | B | 190 hours | B | B |
| Example 15 | 90 | 2 | 20 | B | A | B | 280 hours | B | B |
| Example 16 | 90 | 1 | 35 | B | C | B | 160 hours | B | B |
| Example 17 | 90 | 2 | 10 | B | A | B | 210 hours | A | B |
| Example 18 | 90 | 2 | 20 | B | A | B | 280 hours | B | B |
| Example 19 | 90 | 2 | 25 | B | B | B | 200 hours | B | B |
| Comparative | 90 | 2 | 50 | D | D | C | 155 hours | D | D |
| Example 1 | | | | | | | | | |
| Comparative | 90 | 2 | 42 | D | C | C | 180 hours | D | D |
| Example 2 | | | | | | | | | |
| Comparative | 90 | 2 | 42 | C | C | D | 180 hours | D | D |
| Example 3 | | | | | | | | | |
| Comparative | 90 | 2 | 45 | D | D | D | 155 hours | D | D |
| Example 4 | | | | | | | | | |
| Comparative | 90 | 2 | 43 | D | D | C | 160 hours | D | D |
| Example 5 | | | | | | | | | |
| Comparative | 90 | 2 | Master pellets could not be fabricated. | | | | | | |
| Example 6 | | | | | | | | | |
| Comparative | 90 | 0 | 50 | D | D | D | 155 hours | D | D |
| Example 7 | | | | | | | | | |
| Comparative | 90 | 2 | 30 | D | D | D | 140 hours | D | D |
| Example 8 | | | | | | | | | |
| Comparative | 90 | 2 | 30 | D | D | D | 120 hours | D | D |
| Example 9 | | | | | | | | | |

As shown from Table 1 above, it could be seen that the resin composition of each Example produced by the production method of the present invention has low carbodiimide decomposition rate. It could also be seen that the polyethylene terephthalate film of each Example produced using the resin composition of each Example as a master pellet has excellent hydrolysis resistance. Further, the back sheet for a solar cell module of each Example using the polyethylene terephthalate film of each Example had good adhesion even after wet heat aging.

In addition, the present invention is not limited to exhibit the following effects, but if the polyethylene terephthalate film of each Example is produced using the resin composition of each Example as a master pellet of an end capping agent, the contaminations in the process of film formation are reduced and the variation in film thickness is also low. Further, the obtained polyethylene terephthalate film of each Example had excellent surface shape and heat resistance.

On the other hand, in the resin composition of Comparative Example 1 produced so that the number of screw rotations during the melt-kneading might be over the upper limit of the present invention and the maximum temperature of the barrel might be over the upper limit of the present invention, the carbodiimide decomposition rate was found to be over the upper limit of the present invention. It could be seen that the polyethylene terephthalate film of Comparative Example 1 produced using the resin composition of Comparative Example 1 as a master pellet of an end capping agent was deteriorated in the hydrolysis resistance.

In the resin composition of Comparative Example 2 produced so that the number of screw rotations during the melt-kneading might be over the upper limit of the present invention, the carbodiimide decomposition rate was found to be over the upper limit of the present invention. It could be seen that the polyethylene terephthalate film of Comparative Example 2 produced using the resin composition of Comparative Example 2 as a master pellet of an end capping agent was deteriorated in the hydrolysis resistance.

In the resin composition of Comparative Example 3 produced so that the number of screw rotations during the melt-kneading might be below the lower limit of the present invention, the carbodiimide decomposition rate was found to be over the upper limit of the present invention. It could be seen that the polyethylene terephthalate film of Comparative Example 3 produced using the resin composition of Comparative Example 3 as a master pellet of an end capping agent was deteriorated in the hydrolysis resistance.

In the resin compositions of Comparative Examples 4 and 5 produced so that the maximum temperature of the barrel during the melt-kneading might be over the upper limit of the present invention, the carbodiimide decomposition rate was found to be over the upper limit of the present invention. It could be seen that the polyethylene terephthalate films of Comparative Examples 4 and 5 produced using the resin compositions of Comparative Examples 4 and 5 as a master pellet of an end capping agent was deteriorated in the hydrolysis resistance.

In Comparative Example 6 in which the maximum temperature of the barrel during the melt-kneading might be below the lower limit of the present invention, master pellets cannot be fabricated.

In the resin composition of Comparative Example 7 produced using a double-screw kneader having no vent not included in the range of the present invention, the carbodiimide decomposition rate was found to be over the upper limit of the present invention. It could be seen that the polyethylene terephthalate film of Comparative Example 7 produced using the resin composition of Comparative Example 7 as a master pellet of an end capping agent was deteriorated in the hydrolysis resistance.

It could be seen that the polyethylene terephthalate films of Comparative Examples 8 and 9 produced using the resin compositions of Comparative Examples 8 and 9, which use the polybutylene terephthalate not included in the range of the present invention, as a master pellet of an end capping agent was deteriorated in the hydrolysis resistance.

In addition, it could be seen that all the back sheets for a solar cell module, using the polyethylene terephthalate films produced in the respective Comparative Examples were deteriorated in the adhesion after wet heat aging.

[Fabrication of Solar Cell Module]

The back sheet for a solar cell module of each Example fabricated as described above was bonded to a transparent filler to form the structure as in FIG. 1 in JP-A-2009-158952, thereby fabricating a solar cell module. At this time, adhesion was made such that the readily adhesive layer of the back sheet for a solar cell module of each Example was in contact with the transparent filler in which solar cells were embedded.

It was confirmed that the solar cell module thus fabricated can be developed stably over a long period of time.

While the present invention has been described in detail and with reference to specific embodiments thereof, it will be apparent to one skilled in the art that various changes and modifications can be made therein without departing from the spirit and scope thereof.

The present disclosure relates to the subject matter contained in International Application No. PCT/JP2013/051700, filed Jan. 28, 2013; and Japanese Patent Application No. 2012-021865 filed on Feb. 3, 2012, the contents of which are expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims.

### REFERENCE SIGNS LIST

1 hopper
2 barrel
3 downstream-most barrel

What is claimed is:

1. A resin composition comprising:
a polymer obtained by reacting polyethylene terephthalate with polycarbodiimide,
wherein the decomposition rate of polycarbodiimide is from 1% to 40%.

2. The resin composition according to claim 1, wherein the decomposition rate of polycarbodiimide is from 1% to 30%.

3. A method for producing a resin composition, comprising:
introducing a raw material composition containing polyethylene terephthalate and polycarbodiimide into a double-screw kneader having at least one barrel, a screw, and a vent; and
melt-mixing the raw material composition in the double-screw kneader,
wherein the number of screw rotations of the double-screw kneader is controlled to from 80 rpm to 170 rpm, and
the maximum temperature, Tmax, of the barrel of the double-screw kneader is controlled to satisfy the following formula (1):
Tm−5° C.≦Tmax≦Tm+15° C. Formula (1)
wherein Tm represents the melting point of polyethylene terephthalate expressed by an unit of ° C., and Tmax represents the maximum temperature of the barrel expressed by an unit of ° C.

4. The method for producing a resin composition according to claim 3, wherein the number of screw rotations of the double-screw kneader is controlled to from 80 rpm to 150 rpm.

5. The method for producing a resin composition according to claim 3, wherein the double-screw kneader comprises as the barrel a C1 barrel to which the raw material composition is introduced, and at least one other barrel arranged to be adjacent to the downstream of the C1 barrel, and
the temperature of the C1 barrel is controlled to be lower than the melting point of polycarbodiimide by 10° C. or more.

6. The method for producing a resin composition according to claim 3, wherein the double-screw kneader comprises as the barrel a C1 barrel to which the raw material composition is introduced, a C2 barrel arranged to be adjacent to the downstream of the C1 barrel, and C3 barrel arranged to be adjacent to the downstream of the C2 barrel, and
the minimum temperature, Tmin, of the barrel after the C3 barrel satisfies the following formula (2):
Tm−15° C.≧Tmin≧Tm−65° C. Formula (2)
wherein Tm represents the melting point of polyethylene terephthalate expressed by an unit of ° C., and Tmin represents the minimum temperature of the barrel expressed by an unit of ° C.

7. The method for producing a resin composition according to claim 3, wherein the polyethylene terephthalate has a water content at a time of introduction into the double-screw kneader of 150 ppm or less.

8. The method for producing a resin composition according to claim 3, wherein the polyethylene terephthalate has a temperature at a time of introduction into the double-screw kneader of 160° C. or lower.

9. The method for producing a resin composition according to claim 3, wherein the double-screw kneader has two or more vents.

10. A resin composition produced by:
introducing a raw material composition containing polyethylene terephthalate and polycarbodiimide into a double-screw kneader having at least one barrel, a screw, and a vent; and
melt-mixing the raw material composition in the double-screw kneader,
wherein the number of screw rotations of the double-screw kneader is controlled to from 80 rpm to 170 rpm, and
the maximum temperature, Tmax, of the barrel of the double-screw kneader is controlled to satisfy the following formula (1):
Tm−5° C.≦Tmax≦Tm+15° C. Formula (1)
wherein Tm represents the melting point of polyethylene terephthalate expressed by an unit of ° C., and Tmax represents the maximum temperature of the barrel expressed by an unit of ° C.

11. A polyethylene terephthalate film fabricated by addition of a resin composition comprising a polymer obtained by reacting polyethylene terephthalate with polycarbodiimide, wherein the decomposition rate of polycarbodiimide is from 1% to 40%.

12. A back sheet for a solar cell module, comprising a polyethylene terephthalate film fabricated by addition of a resin composition comprising a polymer obtained by reacting polyethylene terephthalate with polycarbodiimide, wherein the decomposition rate of polycarbodiimide is from 1% to 40%.
